(19) United States
(12) Patent Application Publication
(10) Pub. No.: US 2004/0163030 A1
(43) Pub. Date: Aug. 19, 2004

(54) ITERATIVE ERROR CORRECTING SYSTEM

(75) Inventors: Allen P. Haar, Essex Junction, VT (US); Usha L. Pillai, South Burlington, VT (US)

Correspondence Address: FREDERICK W. GIBB, III, MCGINN & GIBB, PLLC, 2568-A RIVA ROAD, SUITE 304, ANNAPOLIS, MD, 21401, US

(73) Assignee: International Business Machines Corporation, Armonk, NY

(21) Appl. No.: 10/248,733

(22) Filed: Feb. 13, 2003

(51) Int. Cl. G06F 11/00; H03M 13/00

(52) U.S. Cl. 714/800

(57) ABSTRACT

A method and structure for a system for decoding a parity encoded data signal. A multiplexor has a first input adapted to receive said data signal. A plurality of decoders are connected to the multiplexor. The multiplexor uses the decoders in a decoding process to decode the data signal into a corrected data signal and to repeat the decoding process on the corrected data signal. The multiplexor can include a second input that receives the corrected data signal output by the decoders.

### BACKGROUND OF INVENTION

1. Field of the Invention

The present invention generally relates to a parity encoder/decoder and more particularly to an improved iterative error correcting parity encoder/decoder.

2. Description of the Related Art

Data that is transmitted over data channels often becomes mixed with the noise that exists on the data communication channels. In order to remove the noise from the data, it is common to add a parity code to the data, transmit the data over the data channel, decode the data to perform parity correction as necessary and then remove the parity code from the data. The invention described below improves the process of correcting the data in such a parity encoded system.

### SUMMARY OF INVENTION

The invention provides a system for decoding a parity encoded data signal. The multiplexor has a first input adapted to receive said data signal. Decoders are connected to the multiplexor. The multiplexor uses the decoders in a decoding process to decode the data signal into a corrected data signal and to repeat the decoding process on the corrected data signal. The multiplexor can include a second input that receives the corrected data signal output by the decoders. The decoding process can be repeated multiple times on the partially corrected data signal that may not be completely error free. The multiplexor can also have a controller that controls the number of times the decoding process is repeated on the data signal. The decoding process can be repeated on the data signal until the data signal is error-free, or a predetermined number of times. The decoders can include a plurality of serially connected decoders and inverse permuters. The decoders can also include a plurality of serially connected permuters, decoders, and inverse permuters.

The invention also provides a method for decoding a parity encoded data signal. The invention receives an encoded data signal and decodes the data signal to produce the corrected data signal. The invention then repeats the decoding process on the corrected data signal.

### BRIEF DESCRIPTION OF DRAWINGS

The invention will be better understood from the following detailed description of preferred embodiments of the invention with reference to the drawings, in which:

FIG. 1 is a schematic diagram of a parity encoder that utilizes a single parity constraint;

FIG. 2 is a schematic diagram of a parity decoder for a single parity encoded data stream that decodes in a single pass;

FIG. 3 is a schematic diagram of a parity encoder that utilizes multiple parity constraints; 4 is a schematic diagram of a parity encoder that utilizes multiple parity constraints;

FIG. 5 is a schematic diagram of a parity decoder for a multiple parity constraint encoded data stream that decodes in a single pass;

FIG. 6 is a schematic diagram of a parity decoder for a multiple parity encoded data stream that decodes in a single pass;

FIG. 7 is a schematic diagram of a parity decoder for a multiple parity encoded data stream that decodes in multiple passes;

FIG. 8 is a schematic diagram of a parity decoder for a multiple parity encoded data stream that decodes in multiple passes; and

FIG. 9 is a flow diagram illustrating a preferred method of the invention.

### DETAILED DESCRIPTION

The invention comprises an Error Correcting Codes (ECC) encoding/decoding system that is sometimes referred to herein as an Iterative ECC. An ECC is generally designed with the intent to optimize any one or a combination of the following factors: bit error rate (BER), parity overhead and encoder/decoder circuit complexity.

The inventive Iterative Error Correcting Code allows increased performance, in the form of reduced BER, when compared with a Product Code of equivalent parity. This increase in performance is enabled via an information sharing approach. Iterative ECC may be applied to Reed-Solomon (RS) codes, BCH codes, Hamming codes and many other codes, making it a very versatile error correcting methodology.

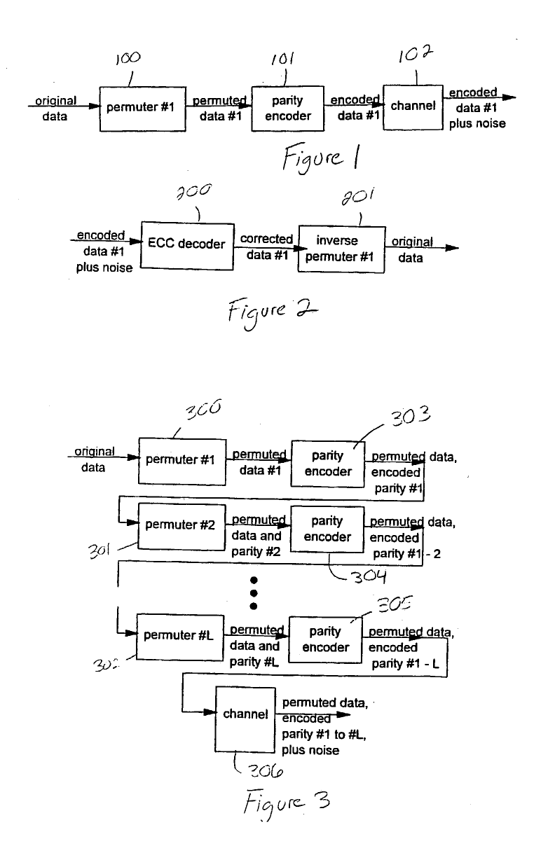

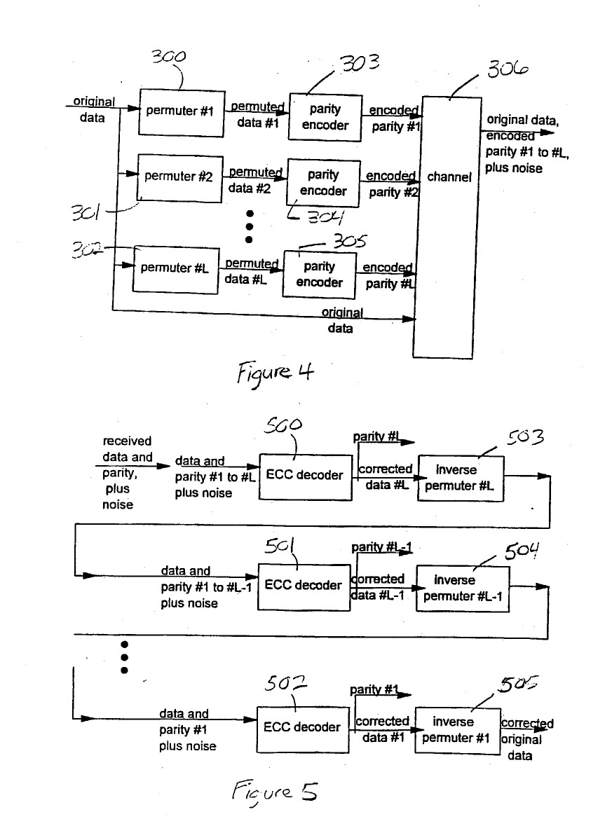

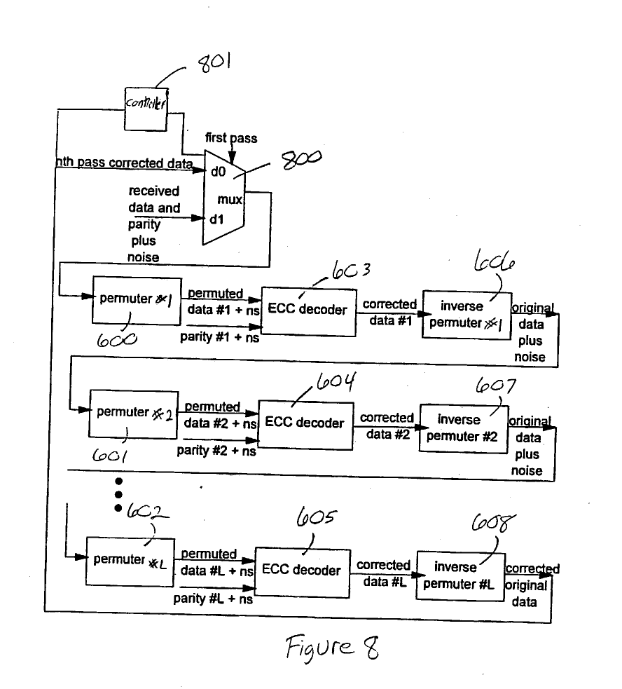

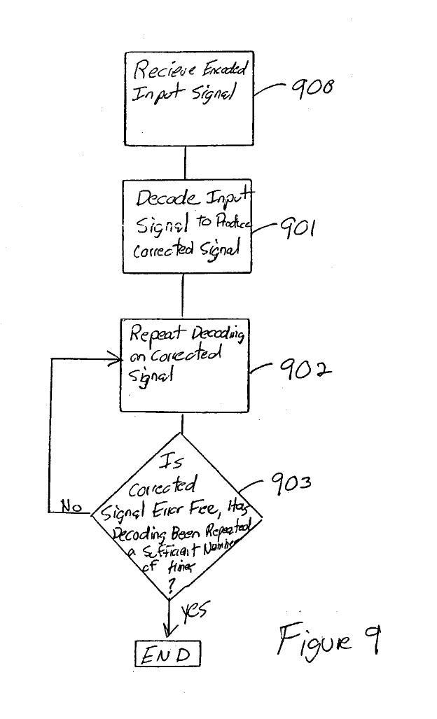

The Iterative Error Correcting Code offers its performance advantage through information passing. To illustrate this, described below are cases that consider three types of error correcting systems. The first system/method (shown in FIGS. 1 and 2) is a single pass algorithm with original data and one set of parity or syndrome constraints. The second system/method (shown in FIGS. 3-6) is a single pass algorithm using L unique sets of permuted data each with identical parity or syndrome constraints. The third system/method type (shown in FIGS. 7-8) is a multiple pass algorithm using L unique sets of permuted data, each with identical parity or syndrome constraints.

These three examples can be applied to the ECC core by the well-known Reed-Solomon code that is capable of correcting (N-K)/2 symbol errors. The number of parity or syndrome symbols is, thus, N-K since the encoded message comprises of message data and parity symbols. In this case, the Reed-Solomon code is commonly referred to as an (N,K) code. While the invention may be applied to RS codes, as would be known by one ordinarily skilled in this art field, the invention is equally applicable to all similar forms of parity error correction.

In the first example shown in FIG. 1, the input data is encoded by the parity encoder 101 once following an optimal permutation step performed by the permuter 100. For the sake of generality, the permutation step is included in these examples.

For the specific case, when the original data is encoded as it is, the permuter 100 will be assumed to pass the data through it without any reordering. The output of the permuter 100 is used to create the parity, as illustrated in FIG. 1.

The parity encoder, as earlier stated, may be any kind of ECC ranging from a single bit of global parity to many parity equations over multibit symbols. The permuted data and parity are transmitted through the channel 102 where noise may corrupt the data and/or parity. When the data is received at the other end of the channel, it is generally decoded and corrected for errors, as illustrated in FIG. 2.

The decoder 200 receives the data and parity message that has been corrupted by noise and corrects all errors up to and including a certain quantity which is generally referred to as the code's correction capability. When the data is successfully decoded by the decoder 200, the parity is removed and the data is inverse permuted by the inverse permuter 201 to obtain the original error-free data.

In the second method, the input data is used L times to create different sets of parity constraints, as illustrated in FIG. 3. The original data is first permuted with a first permuter 300 and then parity encoded with a first parity encoder 303 having a first set of parity constraints. The permuted data and the first set of parity constraints become the input to the second permuter 301 and the second parity encoder 304 that has a second set of parity constraints. This process is repeated through the additional permuters 302 and parity encoders 305 until L sets of parity constraints have been applied. The data and L sets of parity are then transmitted over the noisy channel 306.

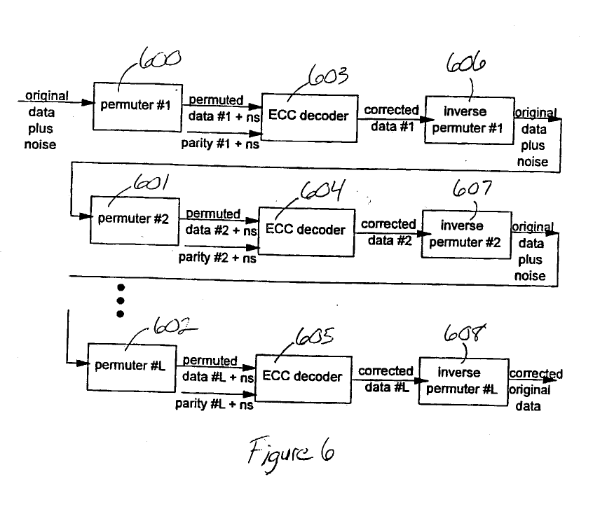

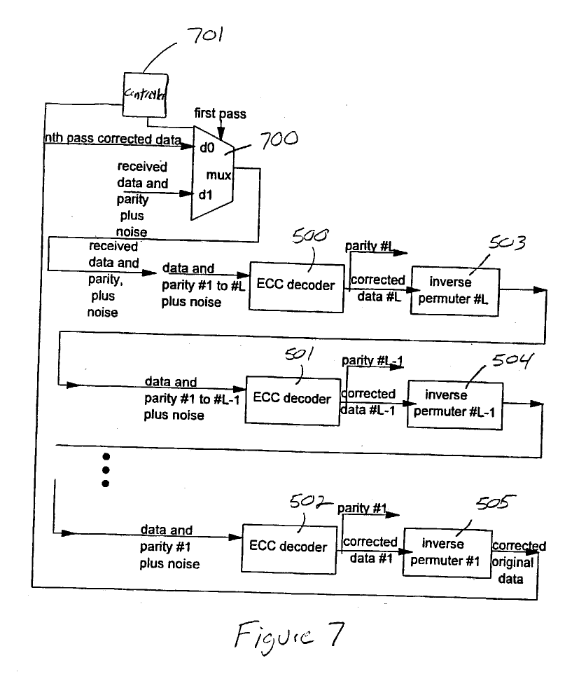

As shown in FIG. 3, each previous parity encoding step becomes part of the input for the next encoding step. The encoding in this second method may also be performed in an alternative embodiment where each of the L parity constraints is computed with only the permuted original data as input to the corresponding parity encoder as illustrated in FIG. 4. Thus, with the system shown in FIG. 4, each set of parity constraints is applied to the data separately instead of collectively as in FIG. 3. By providing parity constraints on the permuted data alone (as shown in FIG. 4), the overhead rate of the code can be made smaller than that of the code where prior parity constraints are passed on to subsequent parity encoders (as shown in FIG. 3). The corresponding decoders for the two encoding structures that are illustrated in FIGS. 3 and 4 are depicted in FIGS. 5 and 6, respectively.

The decoder in FIG. 5 assumes the prior parity encoding of FIG. 3. Therefore, the decoding and the permuting processes are performed in the reverse order to the encoding and permutations in FIG. 3. At the output of each ECC decoder 500-502, the parity for that decoder is stripped off of the ongoing data stream before passing to the inverse permuters 503-505.

The decoding illustrated in FIG. 6 is done in a serial fashion processing through the permuters 600-602, to the ECC decoders 603-605, and to the inverse permuters 606-608 so that the benefit of each decoding stage is realized as reduced rate of errors in the input to the next decoder 603-605. However, the order of the decoders in FIG. 6 is arbitrary, one could as well, for example, decode with the second parity constraint, followed by the last, then the first, and so on. The system in FIG. 6 uses the original data and permutes the data to the correct order for a corresponding decoder 603-605 using permuters 600-602. With such a system, the parity overhead corresponding to a given decoder is only present at that decoder and, therefore, requires no permuting or inverse permuting. Since it does not re-use the parity, this second method shown in FIGS. 3-6 is referred to as a single pass product or multidimensional code algorithm.

In the third method shown in FIGS. 7 and 8, the input data is used L times to create L different sets of parity constraints during the encoding process, as previously discussed with the systems shown in FIGS. 3 and 4. Thus, the second and third methods utilize identical encoding structures for parity generation. However, the decoding structures utilized in the two methods are different. While the second method (FIGS. 5-6) utilizes a single pass in its decoding, the third method (FIGS. 7-8) makes use of a multiple pass system. More specifically, the system shown in FIG. 7 would be used to decode a signal coded using the system shown in FIG. 3 while the system shown in FIG. 8 would be used to decode a signal coded using the system shown in FIG. 4.

In both of the ECC decoding techniques used in the third method (FIGS. 7-8), the decoders 500-502, 603-605 are used in multiple decoding passes. The first decoding pass is identical to that used in the second method (one pass) where the data is appropriately decoded and permuted one time for each set of parity constraints. However, in the third system (FIGS. 7-8), following this initial decoding pass on the data, the partially corrected data is sent in for additional decoding using a multiplexor (mux) 700, 800 to control the selection of the data.

In the first pass, the mux 700, 800 selects input d1 to process the received data and the parity from the channel 306, each corrupted with noise and not having undergone at least one complete decoding pass. After the initial pass, the multiplexor 700, 800 selects input d0 to repeat the decoding process on the previously corrected (decoded) data. The multi-pass system may be terminated either after a fixed number of iterations or when the parity constraints of any of the L decoders indicates error-free data or using any well-known controller 701, 801 attached to or made part of the multiplexor 700, 800. In the former case, each iteration need not each use L decoders, but may end after decoding with one or more of the L decoders for the n-th pass.

FIG. 9 illustrates if the processing of the invention in flowchart form. Beginning at item 900, the invention receives the encoded input signal. In item 901, the invention decodes the input signal to produce the corrected signal. Then, the invention repeats the decoding process on the corrected signal, as shown in item 902.

In item 903, the invention checks whether the corrected signal is error free and/or whether the decoding process has been repeated a sufficient number of times. If the data is error free and/or the process has been repeated a sufficient number of times, processing ends, if not processing returns to item 902.

One benefit of the multi-pass or iterative decoding systems shown in FIGS. 7 and 8 is that the original data is not only constrained by L decoders, but each of those decoders can benefit by operating on data that has been corrected and constrained by the other L-1 parity constraints. Also, substantial performance gains are attained through the use of ECC decoder in the third method, i.e., the iterative decoding method. Reduced output BER's for an equivalent overhead code rate is one advantage that iterative Error Correcting Codes of the third method provide over the first two methods.

The invention may be used in many applications, such as magnetic and optical data storage, optical data transmission, copper (metal wire) or cable data transmission, wireless RF communications and satellite communications.

While the invention has been described in terms of preferred embodiments, those skilled in the art will recognize that the invention can be practiced with modification within the spirit and scope of the appended claims.

1. A system for decoding a parity encoded data signal, said system comprising:
a multiplexor adapted to receive said data signal; and
a plurality of decoders connected to said multiplexor,
wherein each of said decoders comprises a different parity constraint, and
wherein said multiplexor is adapted to use said decoders in a decoding process to decode said data signal into a corrected data signal and to repeat said decoding process on said corrected data signal.

2. The system in claim 1, wherein said decoding process is repeated multiple times on said corrected data signal.

3. The system in claim 2, wherein said multiplexor further comprises a controller adapted to control the number of times said decoding process is repeated on said corrected data signal.

4. The system in claim 2, wherein said decoding process is repeated on said corrected data signal until said corrected data signal is error-free.

5. The system in claim 2, wherein said decoding process is repeated on said corrected data signal a predetermined number of times.

6. The system in claim 1, wherein said decoders comprise a plurality of serially connected decoders and inverse permuters.

7. The system in claim 1, wherein said decoders comprise a plurality of serially connected permuters, decoders, and inverse permuters.

8. A system for decoding a parity encoded data signal, said system comprising:
a multiplexor having a first input adapted to receive said data signal; and
a plurality of decoders connected to said multiplexor,
wherein each of said decoders comprises a different parity constraint, and
wherein said multiplexor is adapted to use said decoders in a decoding process to decode said data signal into a corrected data signal and to repeat said decoding process on said corrected data signal, and
wherein said multiplexor includes a second input adapted to receive said corrected data signal output by said decoders.

9. The system in claim 8, wherein said decoding process is repeated multiple times on said corrected data signal.

10. The system in claim 9, wherein said multiplexor further comprises a controller adapted to control the number of times said decoding process is repeated on said corrected data signal.

11. The system in claim 9, wherein said decoding process is repeated on said corrected data signal until said corrected data signal is error-free.

12. The system in claim 9, wherein said decoding process is repeated on said corrected data signal a predetermined number of times.

13. The system in claim 8, wherein said decoders comprise a plurality of serially connected decoders and inverse permuters.

14. The system in claim 8, wherein said decoders comprise a plurality of serially connected permuters, decoders, and inverse permuters.

15. A method for decoding a parity encoded data signal, said method comprising:
receiving an encoded said data signal;
decoding said data signal into a corrected data signal to produce a corrected data signal;
repeating said decoding process on said corrected data signal.

16. The method in claim 15, further comprising controlling the number of times said decoding process is repeated on said corrected data signal.

17. The method in claim 15, wherein said decoding process is repeated on said corrected data signal until said corrected data signal is error-free.

18. The method in claim 15, wherein said decoding process is repeated on said corrected data signal a predetermined number of times.

19. The method in claim 15, wherein said decoding process is performed using a plurality of serially connected decoders and inverse permuters.

20. The method in claim 15, wherein said decoding process is performed using a plurality of serially connected permuters, decoders, and inverse permuters.

21. A system for encoding and decoding a parity encoded data signal, said system comprising:
a transmitter comprising a plurality of serially connected encoders, wherein each of said encoders has a different parity constraint and wherein a data signal is repeatedly encoded by being passed through said encoders before being output; and
a receiver comprising a multiplexor adapted to receive said data signal and a plurality of decoders connected to said multiplexor,
wherein said multiplexor is adapted to use said decoders in a decoding process to decode said data signal into a corrected data signal and to repeat said decoding process on said corrected data signal.

22. The system in claim 21, further comprising a plurality of permuters serially interspersed with said encoders.

23. The system in claim 21, wherein each successive encoder adds an additional parity constraint to previous parity constraints added by previous encoders to said data signal.

24. The system in claim 21, wherein said decoding process is repeated multiple times on said corrected data signal.

25. The system in claim 21, wherein said multiplexor further comprises a controller adapted to control the number of times said decoding process is repeated on said corrected data signal.

26. The system in claim 21, wherein said decoding process is repeated on said corrected data signal until said corrected data signal is error-free.

27. The system in claim 21, wherein said decoding process is repeated on said corrected data signal a predetermined number of times.

28. The system in claim 11, wherein said decoders comprise a plurality of serially connected decoders and inverse permuters.

29. The system in claim 11, wherein said decoders comprise a plurality of serially connected permuters, decoders, and inverse permuters.
